(19) United States
(12) Patent Application Publication
(10) Pub. No.: US 2022/0159881 A1
(43) Pub. Date: May 19, 2022

(54) INFORMATION APPARATUS

(71) Applicant: LENOVO (SINGAPORE) PTE. LTD., SINGAPORE (SG)

(72) Inventors: Ryota Watanabe, YOKOHAMA (JP); Atsushi Ohyama, YOKOHAMA (JP); Akinori Uchino, YOKOHAMA (JP)

(73) Assignee: LENOVO (SINGAPORE) PTE. LTD., SINGAPORE (SG)

(21) Appl. No.: 17/447,811

(22) Filed: Sep. 15, 2021

(30) Foreign Application Priority Data
Nov. 13, 2020 (JP) 2020189398

(51) Int. Cl. H05K 7/20; G06F 1/20

(52) U.S. Cl. CPC H05K 7/20963; G06F 1/206; G06F 1/203

(57) ABSTRACT

An information apparatus includes a main body chassis having a CPU and a display chassis having a display, the main body chassis and the display chassis being rotatably connected at their respective connecting edge parts. The information apparatus includes a vapor chamber provided in the main body chassis and thermally connected to the CPU, a display controller provided in the main body chassis and controlling display of the display, an FPC connecting the display controller and the display through the connecting edge parts, and a graphite sheet thermally connected to the vapor chamber, overlaid with the FPC to pass through the connecting edge parts, and provided extending from the main body chassis to the display chassis. The graphite sheet is connected to a rear cover.

### FIELD OF THE INVENTION

The present invention relates to an information apparatus including a main body chassis having electric components being heating elements and a display chassis having a display device, the main body chassis and the display chassis being rotatably connected at their respective connecting edge parts.

### BACKGROUND OF THE INVENTION

An information apparatus includes heating elements such as a CPU and the like and needs to be provided with a heat dissipation means depending on the extent of heat generation. An example of the heat dissipation means is a fan. However, in a thin-type information apparatus such as a laptop PC, there is a limit to the thickness of the fan and no sufficient heat dissipation action can be obtained, and thus a heat dissipation plate like a vapor chamber may be used in combination. The vapor chamber is disclosed in Japanese Unexamined Patent Application Publication No. 2019-032134, for example.

### SUMMARY OF THE INVENTION

In a foldable information apparatus such as a laptop PC, heating elements such as a CPU and the like are provided in a main body chassis and a display is provided in a display chassis. The main body chassis is provided with a battery etc. in addition to a main board including the CPU. Although the larger the area of the heat dissipation plate, the more excellent the heat dissipation effect, there are concerns that a battery's life may be shortened if it is heated by overlapping with the heat dissipation plate. In addition, when the heat dissipation plate is located in an armrest part of the laptop PC close to a user, the armrest will be heated and thus user satisfaction cannot be achieved. Although it is also necessary to thin the fan in order to further thin the information apparatus, there is a limit to enlarging the heat dissipation plate accordingly, for the above-described reasons.

On the other hand, in the information apparatus such as a laptop PC, enlarging the display and thinning a bezel surrounding it are desired. Thus, it is becoming difficult to secure a layout space for a display controller in the display chassis, and disposing the controller in the main body chassis is considered. However, the display controller may also generate heat to a certain extent, and thus there are concerns that it becomes difficult for a conventional heat dissipation plate to sufficiently dissipate heat.

The present invention has been made in view of the above-described problem and has an object to provide an information apparatus capable of causing electronic components in the main body chassis to further dissipate heat.

In order to solve the above-mentioned problem and achieve the object, an information apparatus according to the aspect of the present invention is an information apparatus, including a main body chassis having electric components being heating elements and a display chassis having a display, the main body chassis and the display chassis being rotatably connected at their respective connecting edge parts, the information apparatus including: a heat dissipation plate provided in the main body chassis and thermally connected to the electric components; a display control component provided in the main body chassis and configured to control display of the display; a flexible substrate connecting the display control component and the display through the connecting edge parts; and a thermal conductive sheet thermally connected to the heat dissipation plate and provided extending from the main body chassis to the display chassis while being at least partially overlaid with the flexible substrate at the connecting edge parts.

Thus, when the thermal conductive sheet thermally connected to the heat dissipation plate is provided extending from the main body chassis through the connecting edge parts to the display chassis, the heat of the heat dissipation plate is transferred and dissipated to the display chassis and thus it is possible to cause the electric components in the main body chassis to further dissipate heat.

The flexible substrate and the thermal conductive sheet may have facing surfaces fixed at least partially to each other when passing through the connecting edge parts. This makes length adjustment, management, and handling of the flexible substrate and thermal conductive sheet easy.

The display chassis may have a heat conductive cover covering a surface opposite to a display surface of the display, and the thermal conductive sheet may be thermally connected to the heat conductive cover. With this, the heat of the heat dissipation plate is transferred to the heat conductive cover via the thermal conductive sheet. The heat conductive cover has a moderately wide area and has a good heat dissipation effect.

When the thermal conductive sheet is thermally connected to the display control component, heat dissipation of the display control component is improved.

When the thermal conductive sheet has surfaces covered with resin protective layers, good durability can be obtained.

When the heat dissipation plate is a vapor chamber, a good heat dissipation effect can be obtained.

According to the above-described aspect of the present invention, the heat of the heat dissipation plate is transferred and dissipated to the display chassis and thus it is possible to cause the electric components in the main body chassis to further dissipate heat.

### BRIEF DESCRIPTION OF THE DRAWINGS

FIG. 1 is a perspective view illustrating an information apparatus according to an embodiment.

FIG. 2 is a schematic bottom view of the information apparatus in a state in which a rear cover and a bottom cover are removed.

FIG. 3 is a schematic cross-sectional side view of the information apparatus.

FIG. 4A is a cross-sectional side view in a state in which the display chassis is closed to some extent; and FIG. 4B is a cross-sectional side view in a state in which the display chassis is closed completely until abutting the main body chassis.

### DETAILED DESCRIPTION OF THE INVENTION

Hereinafter, an embodiment of an information apparatus according to the present invention is described in detail based on the drawings. It is to be noted that the present invention is not limited by this embodiment.

Hereinafter, a preferred embodiment of the information apparatus according to the present invention is described in detail with reference to the attached drawings.

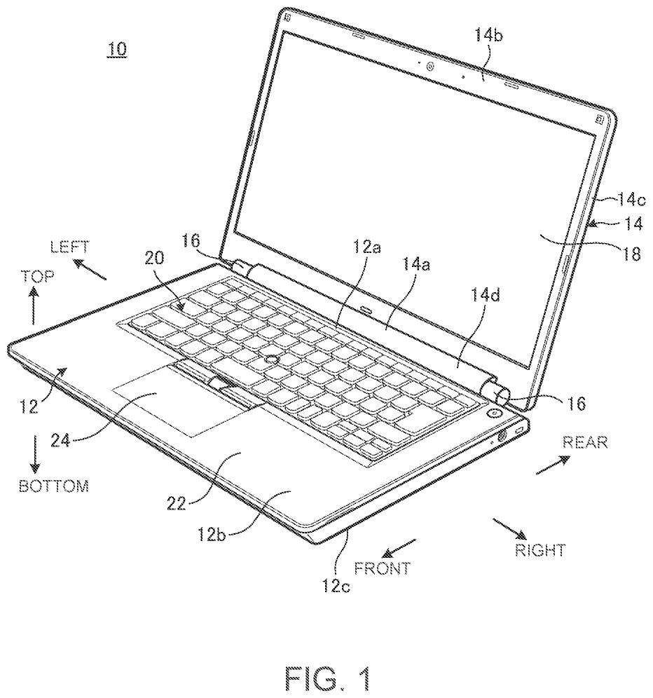

FIG. 1 is a perspective view of an information apparatus 10 according to one embodiment. The information apparatus 10 in the present embodiment is a laptop PC in which a main body chassis 12 and a display chassis 14 are connected by a pair of right and left hinges 16 so that they can rotate at respective connecting edge parts 12a and 14a.

Hereinafter, the information apparatus 10 is described as illustrated in FIG. 1, while based on the direction viewed from a user using the information apparatus 10, the direction toward the user is referred to as front, the direction away from the user is referred to as rear, the thickness direction of the main body chassis 12 is referred to as top and bottom, and the width direction thereof is referred to as right and left.

The display chassis 14 is a thin box-like chassis and is configured by joining a front cover 14b and a rear cover (heat conductive cover) 14c. The front cover 14b is a cover on the same side as a display surface of a display 18 and the rear cover 14c is a cover that covers an entire surface on the opposite side. The rear cover 14c is made of a member having heat conductivity, for example, an aluminum alloy, a magnesium alloy or a carbon material.

The front cover 14b is a narrow frame-like member and the display 18 is provided in a part within the frame. The display 18 is, for example, a liquid crystal display or EL (electroluminescence). In a part including the connecting edge part 14a in the front cover 14b, a cylindrical cover 14d is formed between the pair of hinges 16. A cylindrical surface of the cylindrical cover 14d has a continuous shape with the hinges 16.

The main body chassis 12 is a thin box-like chassis and is configured by joining a top cover 12b and a bottom cover 12c. The top cover 12b is provided with a keyboard 20 at a position that is closer to the rear and with an armrest 22 at a position that is closer to the front. A touch-pad 24 is provided in the center of the armrest 22.

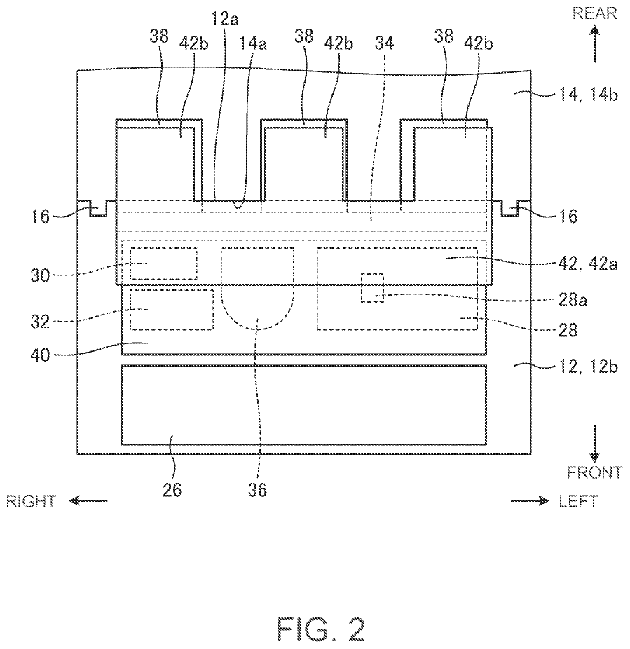

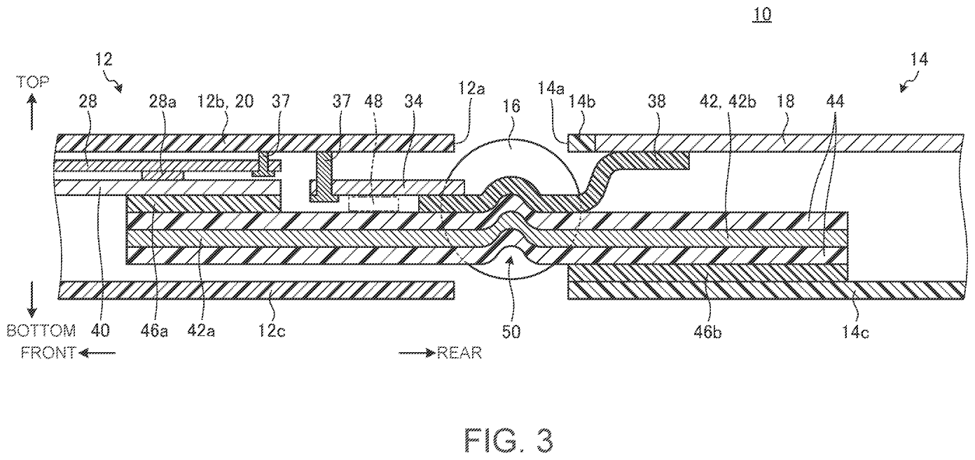

FIG. 2 is a schematic bottom view of the information apparatus 10 in a state in which the rear cover 14c and the bottom cover 12c are removed. The top cover 12b of the main body chassis 12 is provided with a battery 26 at a position that is closer to the front. The battery 26 is disposed at a position substantially overlapping with the above-described armrest 22. The top cover 12b is provided with a main board 28, an SSD (Solid State Drive, electric component) 30, a communication controller (electric component) 32, a display controller (display control component) 34 and a fan 36 in a position that is closer to the rear than the armrest 22. These are disposed at a position substantially overlapping with the above-described keyboard 20. The main board 28 and the display controller 34 etc. are fixed to the keyboard 20 or top cover 12b by screws 37 (refer to FIG. 3) etc.

The main board 28 is a board that integrally controls the information apparatus 10 by a CPU (Central Processing Unit, electric component) 28a mounted thereon. The CPU 28a is an electric component that generates most heat in the information apparatus 10. The SSD 30 is a storage device. The communication controller 32 is compatible with, for example, so-called 5G. The fan 36 is thin according to the thickness of the main body chassis 12.

The display controller 34 is a component that controls at least part of the display control of the display 18. The display controller 34 is, for example, a timing controller to perform display of the display 18. A graphics function part or display memory etc. required for display control may be provided in the main board 28 or may be provided in the display controller 34.

The display controller 34 in the present embodiment is long-shaped and disposed along a rear edge, i.e., the connecting edge part 12a of the main body chassis 12. The display controller 34 is generally provided in the display chassis 14. However, for the information apparatus 10, it is provided in the main body chassis 12. With this, it is possible to narrow the front cover 14b while thinning the display chassis 14 and to enlarge the display 18.

The display controller 34 and the display 18 are electrically connected by three FPC (Flexible printed circuits, flexible substrate) 38 via signal lines etc. The FPC 38 is a substrate obtained by sticking a thin and soft base film having an insulating property and an electrically conductive metal such as a copper foil on which substrate electric circuits can be formed, and has good flexibility. Since the FPC 38 has flexibility, it has sufficient durability against multiple repetitive rotational operations between the main body chassis 12 and the display chassis 14 by the hinges 16.

The three FPCs 38 are arranged in the right-and-left direction and each provided extending from the main body chassis 12 through the connecting edge parts 12a and 14a to the display chassis 14. According to design conditions, the number of the FPCs 38 may be one, two, or four or more. The FPCs 38 pass through a part covered by the cover 14d (refer to FIG. 1) between the main body chassis 12 and the display chassis 14 and are not visible from the user.

The main body chassis 12 is provided with a vapor chamber (heat dissipation plate) 40. The vapor chamber 40 is a plate-like one that is obtained by joining peripheral edges of two metallic plates (for example, copper plates) to form a closed space therein, and can diffuse heat with high efficiency by phase transition of working fluid enclosed in the closed space.

The vapor chamber 40 is rectangular, has a large area, and covers the main board 28, SSD 30, communication controller 32, and fan 36 inside the main body chassis 12. The area covered by the vapor chamber 40 is generally that overlaps with the above-described keyboard 20. The vapor chamber 40 is thermally connected (direct connection, or connection in a form in which heat can be transferred, such as connection via a heat transfer grease etc.) at least to the CPU 28a (refer to FIG. 3). With this, the heat generated by the CPU 28a is transferred to the vapor chamber 40 and the CPU 28a is cooled. The vapor chamber 40 can diffuse the heat received from the CPU 28a over a wide area for heat dissipation. The vapor chamber 40 is also thermally connected to the fan 36 and the heat inside the main body chassis 12 can be released to the outside by air flow of the fan 36. The vapor chamber 40 may be thermally connected to the SSD 30 and communication controller 32.

Although the vapor chamber 40 has a wide area, it does not cover the battery 26. This therefore prevents the heat of the heating elements such as the CPU 28a from being transferred to the battery 26 and does not lead to reduction of life. In addition, the vapor chamber 40 is in a position that does not overlap with the armrest 22 (refer to FIG. 1) and thus the armrest 22 is not heated.

As a heat dissipation means for heat-generating electric components such as the CPU 28a, various heat dissipation plates can be applied other than the vapor chamber 40. The heat dissipation plate includes a metallic plate having high thermal conductivity, for example, copper or aluminum etc., a graphite plate, or a heat lane. It is to be noted that the heat lane is a plate-shaped thermal diffusion component that causes latent heat transport by vapor evaporated by heat absorption of working fluid enclosed in a flow channel formed inside a plate and sensible heat transport due to vibration of the working fluid having liquid phase. Each heat dissipation plate may be additionally provided with a heat pipe. The heat pipe is configured, for example, by crushing a metallic tube whose both ends are joined to form a closed space inside, and is a heat transport device capable of transporting heat with high efficiency by taking advantage of phase change of working fluid enclosed in the closed space.

The main body chassis 12 is further provided with a graphite sheet (thermal conductive sheet) 42. The graphite sheet 42 is a sheet that is composed of graphite as a major component, thin and light, and excellent in heat conductivity and flexibility. The graphite sheet 42 has a right-and-left extending part 42a that extends in the right-and-left direction and is thermally connected to a part of the vapor chamber 40 closer to the rear and three projecting parts 42b that extend from the right-and-left extending part 42a toward the display chassis 14. Thus, the graphite sheet 42 in the present embodiment is substantially E-shaped.

The right-and-left extending part 42a has substantially the same width in the right-and-left direction as the vapor chamber 40 and contacts the vapor chamber 40 by a wide area sufficient for heat conduction. The three projecting parts 42b are each provided extending from the main body chassis 12 through the connecting edge parts 12a and 14a to the display chassis 14 while being overlaid with the FPCs 38.

Thus, the graphite sheet 42 can receive sufficient heat from the vapor chamber 40 and diffuse the heat to the display chassis 14 via the connecting edge parts 12a and 14a since the right-and-left extending part 42a contacts the vapor chamber 40 by a sufficiently wide area. Therefore, the area of the vapor chamber 40 is conceptually not limited within the main body chassis 12, and is expanded to the display chassis 14, and thus it is possible to cause the electric components being heating elements such as the CPU 28a to further dissipate heat.

In addition, the graphite sheet 42 can share an area for a flexible member reserved for the FPCs 38 to be passed between the main body chassis 12 and the display chassis 14, by being overlaid with the FPCs 38. The effect of sharing the area for a flexible member can be obtained accordingly, as long as the projecting parts 42b of the graphite sheet 42 are at least partially overlaid with the FPCs 38 at the connecting edge parts 12a and 14a. In the present embodiment, the three projecting parts 42b are each substantially entirely overlaid with the FPCs 38, and thus the width of the area for a flexible member for insertion between the main body chassis 12 and the display chassis 14 can be significantly narrowed. Instead of the graphite sheet 42, a sheet having heat conductivity and flexibility, for example, a copper foil or an aluminum foil may be used.

FIG. 3 is a schematic cross-sectional side view of the information apparatus 10. For ease of understanding, the FPC 38, the graphite sheet 42, resin protective layers 44, and adhesive tapes 46a and 46b are shown thickly in FIG. 3. As illustrated in FIG. 3, both surfaces of the graphite sheet 42 are covered with the resin protective layers 44. The resin protective layer 44 is sufficiently thick to an extent that does not affect the heat conductivity. The resin protective layer 44 is made of polyimide material, for example. Thus, the graphite sheet 42 can obtain durability against multiple repetitive rotational operations of the display chassis 14 and prevent generation of abrasion powders etc. from the surfaces since the surfaces are covered with the resin protective layers 44. The graphite sheet 42 is thermally connected to the vapor chamber 40 at a part of the right-and-left extending part 42a. In particular, it is fixed thereto by the adhesive tape 46a having heat conductivity.

The projecting part 42b of the graphite sheet 42 comes into the display chassis 14 and is thermally connected to an inner surface of the rear cover 14c. In particular, it is fixed thereto by the adhesive tape 46b having heat conductivity.

Thus, the heat of the vapor chamber 40 is transferred to the rear cover 14c via the graphite sheet 42 since the graphite sheet 42 is thermally connected to the rear cover 14c made of heat conductive material such as metal. The rear cover 14c has a moderately wide area and thus has a good heat dissipation effect. This can cause the electric components of heating elements such as the CPU 28a to further dissipate heat. In the display chassis 14, a heat insulating material is provided between the projecting part 42b and the display 18 if required.

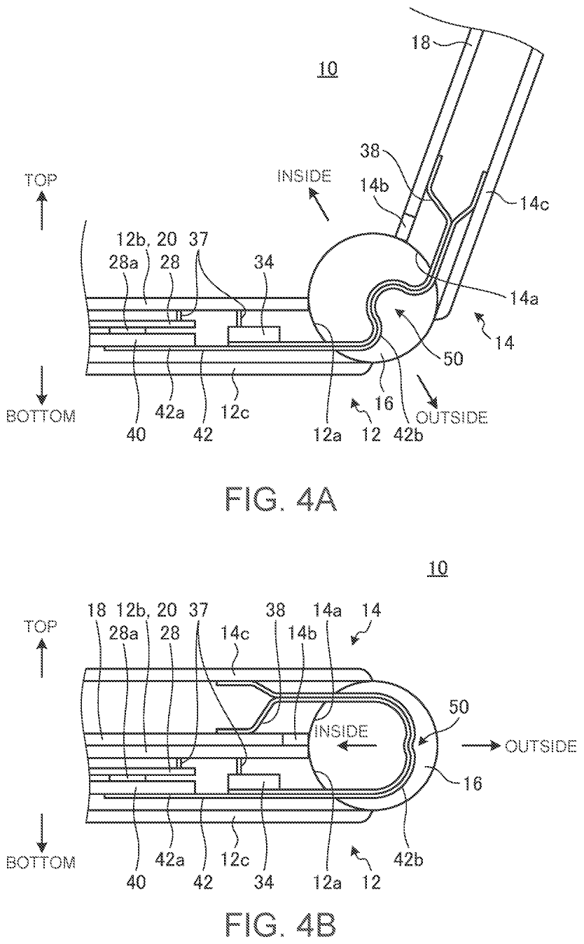

In a state in which the main body chassis 12 and the display chassis 14 are opened until they become substantially flush with each other (state in FIG. 3) and a state in which they are closed to some extent by rotating the display chassis 14 by the hinges 16 to be closer to the main body chassis 12 (refer to FIG. 4A), the lengths of the FPC 38 and the graphite sheet 42 are set so that an appropriate looseness 50 is ensured at a part where they are passed from the main body chassis 12 to the display chassis 14. Surfaces of the FPC 38 and the graphite sheet 42 facing each other are fixed entirely or at least partially at a part passing through the connecting edge parts 12a and 14a. A fixing means is an adhesive tape, for example. It is not indispensable that the FPC 38 and the graphite sheet 42 are fixed. However, if they are fixed to each other, length adjustment, management, and handling become easy so as to ensure the same looseness 50.

When the display controller 34 generates heat to some extent, the display controller 34 and the graphite sheet 42 may be connected by a heat transfer means 48 (for example, heat conductive rubber) if desired.

FIG. 4A is a cross-sectional side view in a state in which the display chassis 14 is closed to some extent; and FIG. 4B is a cross-sectional side view in a state in which the display chassis 14 is closed completely until abutting the main body chassis 12. In FIGS. 4A-4B, when the display chassis 14 rotates to come close to the main body chassis 12, a side with respect to the hinge 16 on which an angle between the main body chassis 12 and the display chassis 14 narrows is made inside, while a side on which the angle extends is made outside.

As illustrated in FIG. 4A, the main board 28 is fixed to an inner surface of the keyboard 20 or top cover 12b by the screw 37. The CPU 28a is mounted on a bottom surface of the main board 28. The vapor chamber 40 is located below the main board 28 and thermally connected to a bottom surface of the CPU 28a. The right-and-left extending part 42a of the graphite sheet 42 is thermally connected to a bottom surface of the vapor chamber 40. That is, a plurality of members is interposed between the graphite sheet 42 and the top cover 12b and thus there is some distance between them. On the other hand, the graphite sheet 42 is close to the bottom cover 12c. Therefore, the graphite sheet 42 is disposed closer to the outside and the looseness 50 projects toward the inside.

As illustrated in FIG. 4B, in the state in which the display chassis 14 is completely closed, the looseness 50 is smaller, and the graphite sheet 42 and FPC 38 projecting from the vicinity of the bottom cover 12c, have a substantially semicircular shape that is closer to the outside and gentle from the connecting edge part 12a to the connecting edge part 14a. Thus, the graphite sheet 42 and FPC 38 are bent gently and less deteriorated even after the rotation is repeated since they are disposed closer to the outside.

Thus, in the information apparatus 10 according to the present embodiment, the heat of the vapor chamber 40 is transferred and dissipated to the display chassis 14 and it is possible to cause the electric components in the main body chassis 12 to further dissipate heat, since the graphite sheet 42 thermally connected to the vapor chamber 40 is provided extending from the main body chassis 12 through the connecting edge parts 12a and 14a to the display chassis 14.

It is a matter of course that the present invention is not limited to the embodiment described above and can be freely altered without deviating from the spirit of the present invention.

1. An information apparatus comprising a main body chassis including electric components that are heating elements and a display chassis including a display, the main body chassis and the display chassis being rotatably connected at their respective connecting edge parts, the information apparatus further comprising:
a heat dissipation plate in the main body chassis and thermally connected to the electric components;
a display control component in the main body chassis and configured to control the display;
a flexible substrate connecting the display control component and the display through the connecting edge parts; and
a thermal conductive sheet thermally connected to the heat dissipation plate and which extends from the main body chassis to the display chassis and at least partially overlay with the flexible substrate at the connecting edge parts.

2. The information apparatus according to claim 1,
wherein the flexible substrate and the thermal conductive sheet have respective facing surfaces fixed at least partially to each other at the connecting edge parts.

3. The information apparatus according to claim 1,
wherein the display chassis has a heat conductive cover covering a surface opposite to a display surface of the display, and
the thermal conductive sheet is thermally connected to the heat conductive cover.

4. The information apparatus according to claim 1,
wherein the thermal conductive sheet is thermally connected to the display control component.

5. The information apparatus according to claim 1,
wherein the thermal conductive sheet has surfaces covered with resin protective layers.

6. The information apparatus according to claim 1,
wherein the heat dissipation plate is a vapor chamber.
